(19) United States
(12) Patent Application Publication
(10) Pub. No.: US 2024/0354244 A1
(43) Pub. Date: Oct. 24, 2024

(54) Mixed Compiling for Memory Units and Logic Units in an Integrated Circuit

(71) Applicant: MEDIATEK INC., Hsin-Chu (TW)

(72) Inventors: Chia-Yu Yang, Hsinchu City (TW); Shu-Rong Lee, Hsinchu City (TW); Cheng-Mu Wu, Hsinchu City (TW); Kim Soon Jway, Singapore (SG); Min-Jen Tsai, Hsinchu City (TW)

(73) Assignee: MEDIATEK INC., Hsin-Chu (TW)

(21) Appl. No.: 18/381,643

(22) Filed: Oct. 19, 2023

Related U.S. Application Data
(60) Provisional application No. 63/497,473, filed on Apr. 21, 2023.

(51) Int. Cl. G06F 12/02

(52) U.S. Cl. CPC G06F 12/023

(57) ABSTRACT

A method for configuring a plurality of memory units and a plurality of logic units in an integrated circuit includes providing a plurality of predefined parameters of the plurality of memory units, parsing the plurality of predefined parameters to generate a plurality of parsed parameters, compiling the plurality of memory units and the plurality of logic units at the same stage to generate a plurality of candidates of mapping results according to the plurality of parsed parameters, selecting a candidate of the mapping results from the plurality of candidates of the mapping results, and disposing the plurality of memory units and the plurality of logic units onto the integrated circuit according to the candidate of the mapping results.

### CROSS REFERENCE TO RELATED APPLICATIONS

This application claims the benefit of U.S. Provisional Application No. 63/497,473, filed on Apr. 21, 2023. The content of the application is incorporated herein by reference.

### BACKGROUND

In the prior art integrated circuit design, a memory complier is performed first to select a set of memory units each having a memory type. Once the memory units are selected, a logic complier carries out a subsequent process to select a set of logic units each having a logic type. That is, the logic compiler performs compiling after the memory compiler.

FIG. 1 is a flowchart of designing an integrated circuit according to the prior art. At first, a memory compiler 10 is performed to select a set of memory units. Secondly, a resistor transistor level (RTL) instance 12 is performed. At last, the logic compiler 14 is performed to select a set of logic units, and to determine whether the integrated circuit (IC) design meets the key performance indicators (KPI) of performance, power, and area (PPA). If the design cannot meet the KPI of performance, power, and area, then the procedure returns to the memory compiler 10 to select another set of memory units, and followed by the logic compiler 14 to select another set of logic units. If the design meets the KPI of performance, power, and area, then the procedure returns the output of the memory compiler 10 and the logic compiler 14.

This iteration takes a long time if the characters of the combination of memory units and logic units are unable to meet the target criteria, such as performance, power or area. Thus it's time consuming to optimize the design of the integrated circuit.

### SUMMARY

A method for configuring a plurality of memory units and a plurality of logic units in an integrated circuit includes providing a plurality of predefined parameters of the plurality of memory units, parsing the plurality of predefined parameters to generate a plurality of parsed parameters, compiling the plurality of memory units and the plurality of logic units at the same stage to generate a plurality of candidates of mapping results according to the plurality of parsed parameters, selecting a candidate of the mapping results from the plurality of candidates of the mapping results, and disposing the plurality of memory units and the plurality of logic units onto the integrated circuit according to the candidate of the mapping results.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flowchart of designing an integrated circuit according to the prior art.

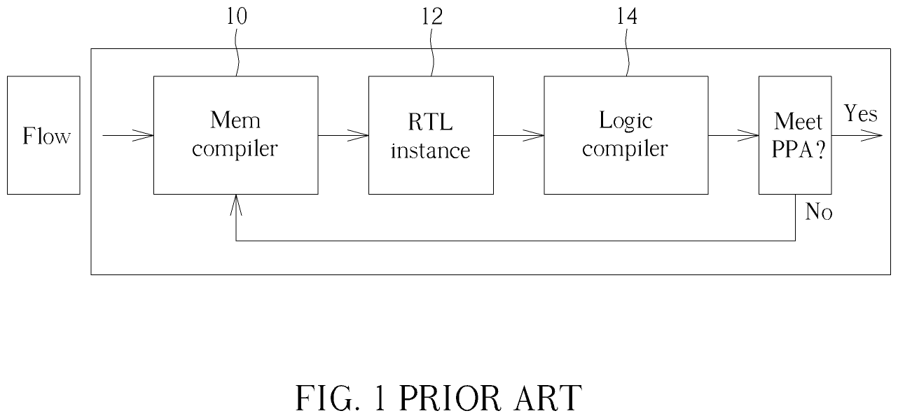

FIG. 2 is a flowchart of designing an integrated circuit according to an embodiment of the present invention.

FIG. 3 shows a unified memory structure (UMS) model and unified memory structure (UMS) wrapper according to an embodiment of the present invention.

FIG. 4 is a detailed flowchart of designing the integrated circuit according to an embodiment of the present invention.

FIG. 5 is the illustration of the unified memory structure compiler in FIG. 4.

FIG. 6 is a flowchart of a method for configuring a plurality of memory units and a plurality of logic units in an integrated circuit according to an embodiment of the present invention.

### DETAILED DESCRIPTION

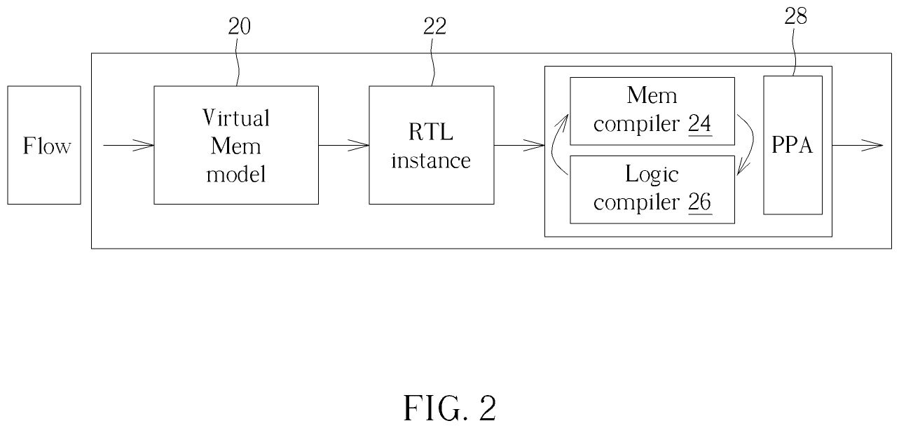

FIG. 2 is a flowchart of designing an integrated circuit according to an embodiment of the present invention. At first, a virtual memory model 20 is inputted to a resistor transistor level (RTL) instance 22. Secondly, the RTL instance 22 is performed for introducing the virtual memory model 20. At last, a memory compiler 24 and a logic compiler 26 are performed in the same stage to select and position a set of memory units and a set of logic units, and check whether the integrated circuit (IC) design meets the key performance indicators (KPI) of performance, power, and area (PPA) 28. If the design cannot meet the KPI of PPA 28, then the memory compiler 24 and the logic compiler 26 are performed to generate another possible solution. If the design meets the KPI of PPA 28, then the procedure returns the output of the memory compiler 24 and the logic compiler 26. In this process, the memory compiler 24 is performed to select and position a set of memory units while the logic compiler 26 is performed to select and position a set of logic units at the same stage. Therefore, PPA 28 can be considered by the memory compiler 24 and the logic compiler 26, resulting in a total solution.

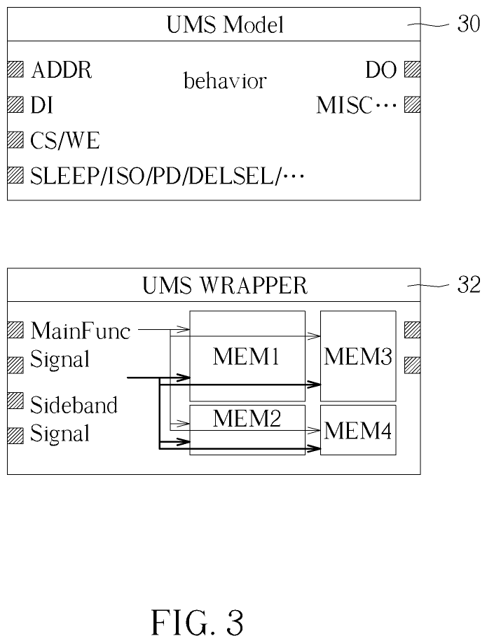

FIG. 3 shows a unified memory structure (UMS) model 30 and unified memory structure (UMS) wrapper 32 according to an embodiment of the present invention. The unified memory structure model 30 contains a plurality of ports including an address port, data in port, data out port, sleep port, and other ports. The unified memory structure model 30 is an easy integration at design stage, and the unified memory structure wrapper 32 is a mixed compiler providing a flexible memory solution. The unified memory structure wrapper 32 contains a plurality of memory units with main function signals and sideband signals. The memory compiler 24 chooses a set of memory units from the plurality of memory units. The set of memory units satisfies required functions and timings. The memory compiler 24 then wraps the set of memory units, and keeps ports of the unified memory structure model 30 intact while maintaining the functions of the set of memory units. That is, the unified memory structure wrapper 32 makes sure functions of the set of memory units and ports of the unified memory structure model 30 are not altered at the mixed compiler stage.

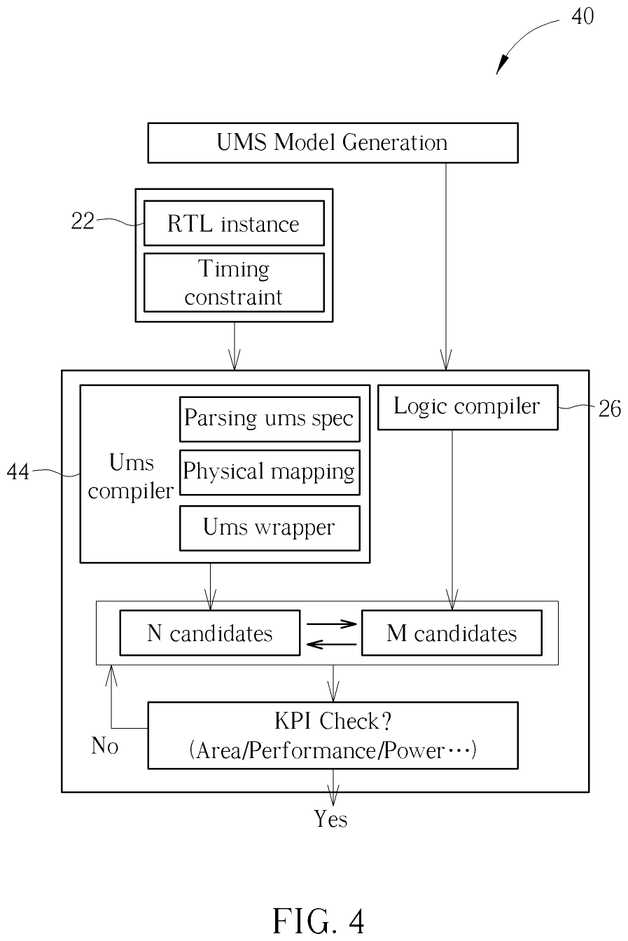

FIG. 4 is a detailed flowchart 40 of designing the integrated circuit according to an embodiment of the present invention. At first, the unified memory structure model 30 to be inputted to a mixed compiler including a unified memory structure compiler 44 and the logic compiler 26 is generated. Secondly, the RTL instance 22 with timing constraint is inputted to the mixed compiler for generating corresponding circuit candidates. The memory and peripheral circuits are included in the candidates. The unified memory structure compiler 44 includes parsing unified memory structure specification, physical mapping, and unified memory structure wrapper 32. N candidates of a plurality of memory units and M candidates of a plurality of logic units can be selected by the mixed compiler. If a selected candidate for the memory units and a selected candidate for the logic units cannot meet key performance indicator (KPI) such as area, power, placement and utilization rate, return to select another candidate for the memory units and another candidate for the logic units. If a selected candidate for the memory units and a selected candidate for the logic units meet key performance indicator (KPI), then the procedure outputs the selected candidate.

The unified memory structure model 30 is defined for the resistor transistor level (RTL) design stage, and physical positions of the memory units and logic units are determined by the mixed compiler. The unified memory structure compiler 44 parses static function specification from the unified memory structure models 30 including model names, ports and configuration files of the unified memory structure models 30. The unified memory structure compiler 44 also parses timing specification from the configuration files and maps one physical memory unit to one UMS model, N physical memory units to one UMS model, or one physical memory unit to N UMS models. The unified memory structure wrapper 32 adds a wrapper circuit to make ports and functions the same as the unified memory structure model 30.

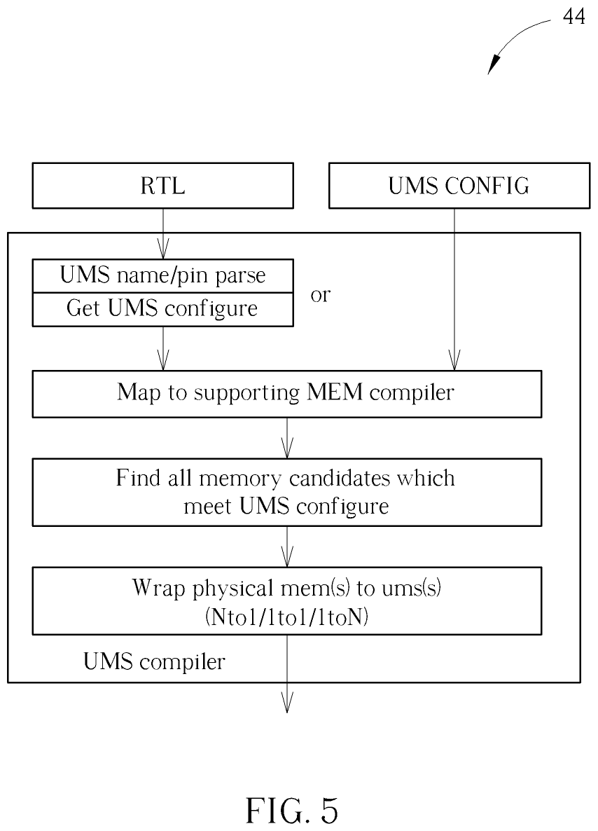

FIG. 5 is the unified memory structure compiler 44 according to an embodiment of the present invention. The unified memory structure model 30 is generated with certain aspects such as a single port, dual ports, or other configuration. Then, the unified memory structure configuration and resistor transistor level configuration are inputted into the unified memory structure compiler 44. The unified memory structure compiler 44 parses the names and ports of the unified memory structure models 30 to generate unified memory structure model configurations and map to the unified memory structure compiler 44. The unified memory structure compiler 44 finds memory candidates which meet unified memory structure model configurations and wrap physical memory units to unified memory structures (N to one, one to one, or one to N).

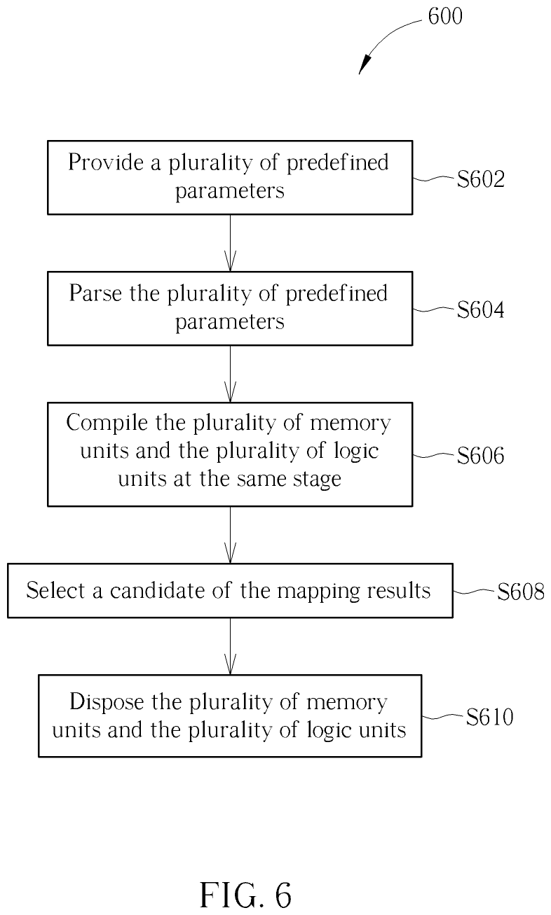

FIG. 6 is a flowchart of a method 600 for configuring a plurality of memory units and a plurality of logic units in an integrated circuit according to an embodiment of the present invention.

Step S602: provide a plurality of predefined parameters of the plurality of memory units;

Step S604: parse the plurality of predefined parameters to generate a plurality of parsed parameters;

Step S606: compile the plurality of memory units and the plurality of logic units at the same stage to generate a plurality of candidates of mapping results according to the plurality of parsed parameters;

Step S608: select a candidate of the mapping results from the plurality of candidates of the mapping results;

Step S610: dispose the plurality of memory units and the plurality of logic units onto the integrated circuit according to the candidate of the mapping results.

The method may be performed by a processor. The plurality of memory units may be contained by a plurality of unified memory structure models 30. In Step S602, the plurality of predefined parameters of the plurality of memory units can comprise model names, ports, functions and configure files of the plurality of unified memory structure models 30.

In Step S606, the plurality of memory units and the plurality of logic units may be compiled by a mixed compiler. The mixed compiler may comprise the unified memory structure compiler 44 and the logic compiler 26. The unified memory structure compiler 44 may be used to compile the plurality of memory units. The logic compiler 26 may be used to compile the plurality of logic units.

In Step S608, the candidate of the mapping results may be selected using a reinforcement learning model with predetermined criteria. The candidate of the mapping results includes the selected memory units and selected logic units, and the positions of the selected memory units and selected logic units on the integrated circuit.

In Step S610, the plurality of memory units and the plurality of logic units may be disposed onto the integrated circuit according to the candidate of the mapping results using a reinforcement learning model with predetermined criteria.

The predetermined criteria in Steps S608 and S610 may comprise power consumption, performance and area of the plurality of memory units and the plurality of logic units.

By using the mixed compiler including the unified memory structure compiler 44 and the logic compiler 26, the plurality of memory units and the plurality of logic units can be selected and disposed onto the integrated circuit at the design stage, providing an easy integration solution, saving designing time, and meeting the key performance indicators (KPI) such as performance, power, and area.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for configuring a plurality of memory units and a plurality of logic units in an integrated circuit, comprising:
providing a plurality of predefined parameters of the plurality of memory units;
parsing the plurality of predefined parameters to generate a plurality of parsed parameters;
compiling the plurality of memory units and the plurality of logic units at the same stage to generate a plurality of candidates of mapping results according to the plurality of parsed parameters;
selecting a candidate of the mapping results from the plurality of candidates of the mapping results; and
disposing the plurality of memory units and the plurality of logic units onto the integrated circuit according to the candidate of the mapping results.

2. The method of claim 1, wherein the plurality of memory units are contained by a plurality of unified memory structure models.

3. The method of claim 2, wherein the plurality of predefined parameters comprises model names, ports, functions and configure files of the plurality of unified memory structure models.

4. The method of claim 1, wherein selecting the candidate of the mapping results from the plurality of candidates of the mapping results is selecting the candidate of the mapping results from the plurality of candidates of the mapping results using a reinforcement learning model with predetermined criteria.

5. The method of claim 4, wherein the predetermined criteria comprise power consumption, performance and area of the plurality of memory units and the plurality of logic units.

6. The method of claim 1, wherein disposing the plurality of memory units and the plurality of logic units onto the integrated circuit according to the candidate of the mapping results is disposing the plurality of memory units and the plurality of logic units onto the integrated circuit according to the candidate of the mapping results using a reinforcement learning model with predetermined criteria.

7. The method of claim 6, wherein the predetermined criteria comprise power consumption, performance and area of the plurality of memory units and the plurality of logic units.

8. The method of claim 1, wherein compiling the plurality of memory units and the plurality of logic units at the same stage is a mixed compiler compiling the plurality of memory units and the plurality of logic units at the same stage.

9. The method of claim 1, wherein compiling the plurality of memory units and the plurality of logic units at the same stage is a unified memory structure compiler compiling the plurality of memory units and a logic compiler compiling the plurality of logic units at the same stage.
